(19) United States
(12) Patent Application Publication
(10) Pub. No.: US 2006/0107987 A1
(43) Pub. Date: May 25, 2006

(54) Computer with heat-recycling function

(75) Inventors: Ga-Lane Chen, Fremont, CA (US); Jhy-Chain Lin, Tu-Cheng (TW); Charles Leu, Fremont, CA (US)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/242,394

(22) Filed: Oct. 3, 2005

(30) Foreign Application Priority Data
Nov. 19, 2004 (TW) 93135549

(51) Int. Cl. H01L 35/30

(52) U.S. Cl. 136/205

(57) ABSTRACT

A computer includes a motherboard, a heat-generating device mounted on the motherboard, a heat-conducting device attached to the heat-generating device for absorbing heat energy generated from the heat-generating device, and a thermoelectric converter coupled to the heat-dissipating device for converting the heat energy into electric energy for recycling use. The heat-conducting device includes a heatpipe. The heatpipe contains a working fluid, which has nano-sized particles therein. The nano-sized particles may be composed of carbon and/or a metallic material. The computer may include a heat-conducting plate interposed between the heatpipe and the heat-generating device. The thermoelectric converter may include a circuit with two strips connected in series, the strips each being formed of a different kind of thermoelectric metal. Corresponding ends of the two strips would be coupled to the heat-conducting device so as to receive heat energy therefrom.

### BACKGROUND OF THE INVENTION

1. Field of the Invention

The present invention relates to computers and, particularly, to a computer having a heat-recycling function.

2. Discussion of the Related Art

A typical CPU (central processing unit) of a computer has nearly 5,500 million transistors incorporated therein. When the CPU is running, a great amount of heat can be generated in a short time. The CPU may operate at temperatures beyond a safe threshold temperature. This can adversely impair performance of the transistors and tends to result in the occurrence of run-time errors. It is estimated that heat energy generated by a standard CPU of a personal computer may increase from the present 30 W/cm² up to 3000 W/cm² by the year 2010, due to progressively increasing integration of transistors into standard CPUs. Therefore, heat dissipation within a CPU is becoming more and more important, in order to ensure that the CPU can work within safe, normal temperature range.

FIG. 2 represents a conventional heat-dissipating device 2, as disclosed in U.S. Pat. No. 6,654,243. The heat-dissipating device 2 comprises a heat sink 20, two fans 22 mounted on the heat sink 20, a thermoconductive plate 24, and a heatpipe 26. The thermoconductive plate 24 is generally brought into contact with a top surface of a CPU (not shown). The thermoconductive plate 24 and the heat sink 20 are interconnected by means of the heatpipe 26. Heat generated by the CPU is absorbed by the thermoconductive plate 24, is transferred to the heat sink 20 through the heatpipe 26, and is then discharged by the fans 22.

The heat-dissipating device 2, by its very nature, does not utilize the heat generated and, instead, merely provides for the dissipation of the heat generated from the CPU. As a consequence, a great amount of heat energy may be discharged out of the computer case, simply wasting such energy.

What is needed, therefore, is a computer having a heat-recycling function. In particular, what is needed is a computer which is capable of converting heat energy generated by heat-generating devices thereof into electrical energy for further use.

### SUMMARY

A computer having a heat-recycling function is provided herein. The computer generally includes a circuit board, a heat-generating device mounted on the circuit board, a heat-conducting device attached to the heat-generating device for absorbing heat energy generated from the heat-generating device, and a thermoelectric converter coupled to the heat-dissipating device, the thermoelectric converter being configured for converting the heat energy into electric energy, thereby recycling the heat energy for further use.

The heat recycling system of the invention, as such, incorporates the heat conducting device and the thermoelectric converter. The heat-conducting device includes a heatpipe. The heatpipe contains a circulatory working fluid, which contains nano-sized particles therein. The nano-sized particles may advantageously be selected from the group consisting of carbon nanotubes, carbon nanocapsules, and a metallic nano-material. A heat-conducting plate may advantageously be interposed between the heatpipe and the particular heat-generating device (e.g., a computer, another electronic/electrical device, an optical device, or an engine/motor). The thermoelectric converter may include a circuit with two strips connected in series. The strips are formed of two different kinds of thermoelectric metals. Corresponding ends of the two strips are coupled to the heat-conducting device. Each of the ends serves as a heat energy source.

The thermoelectric converter, when used within a CPU, can be electrically connected to other electronic elements mounted on the circuit board. Alternatively, the thermoelectric converter could be electrically connected to facilitate the charging of a secondary battery. By doing so, the heat energy, which would be otherwise wasted if employing conventional heat-dissipating devices, is substantially utilized.

Other advantages and novel features will become more apparent from the following detailed description when taken in conjunction with the accompanying drawings.

### BRIEF DESCRIPTION OF THE DRAWINGS

Many aspects of the present heat recycling system can be better understood with reference to the following drawings. The components in the drawings are not necessarily to scale, the emphasis instead being placed upon clearly illustrating the principles of the present heat recycling system. Moreover, in the drawings, like reference numerals designate corresponding parts throughout the several views.

FIG. 1 is schematic, cross-sectional diagram of a portion of a computer having a heat recycling function, according to a preferred embodiment of the present heat recycling system.

FIG. 2 is an exploded, isometric view of a conventional heat-dissipating device for a computer.

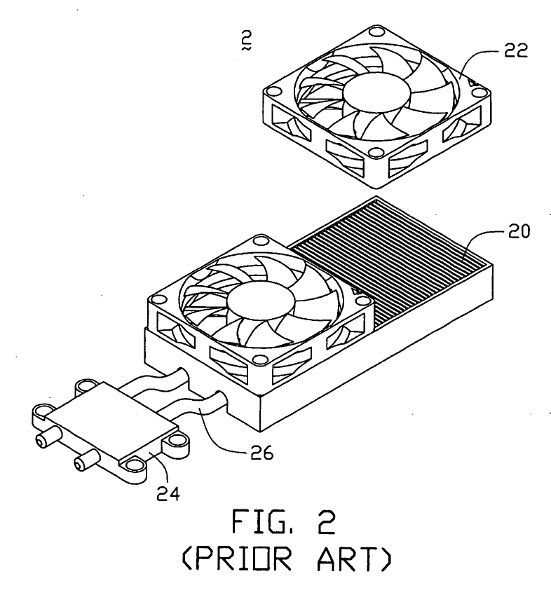

### DETAILED DESCRIPTION OF THE PREFERRED EMBODIMENTS

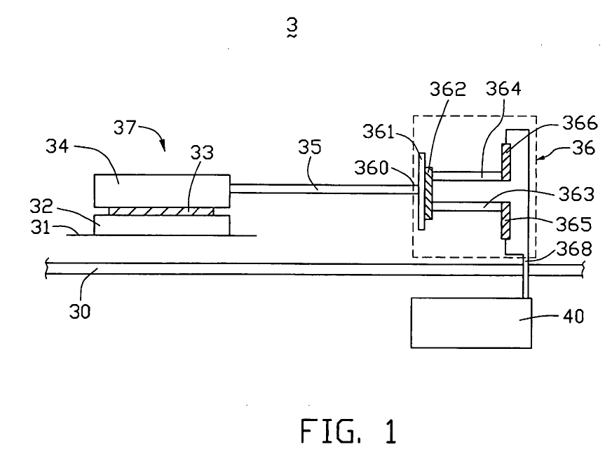

Reference will now be made to the main drawing, FIG. 1, to describe a preferred embodiment of the present heat recycling system in detail.

Referring to FIG. 1, a heat-dissipating device 3, taking the form of a computer in the illustrated embodiment of the present invention, is partly depicted. The computer 3 includes an enclosure 30, a motherboard 31, a heat-generating device 32, a thermal interface material 33, a thermo-conductive block 34, and a heat-conducting device 35. In the illustrated exemplary embodiment, the heat-generating device 32 is a CPU 32. It should be noted, however, that the heat-generating device 32 may be any other of various electronic/electrical elements (e.g., another electronic/electrical component, an optical or opto-electronic device, or a display unit) that generate a certain amount of heat energy. The CPU 32 is mechanically and electrically mounted on the motherboard 31. The thermal interface material 33 is generally interposed between the CPU 32 and the thermo-conductive block 34. The thermal interface material 33 is configured for eliminating air gaps from a thermal interface thereat and thereby improving heat flow through the thermal interface. A first end of the heat-conducting device 35 is coupled to the thermo-conductive block 34.

In the illustrated exemplary embodiment, the heat-conducting device 35 is in the form of a heatpipe 35. It should be noted, however, that the heatpipe 35 may be any other of various suitable heat-absorbing devices 35 that can sufficiently conduct heat energy generated from the heat-generating device 32 (CPU 32).

The computer 3 further comprises a thermoelectric converter 36. The thermoelectric converter 36 described hereinbelow is configured for converting heat energy into electrical energy. A variety of conventional thermoelectric converters are known to those skilled in the art and may be suitably adopted. The following description is of the computer with a thermoelectric converter 36 that operates based on the Seebeck Effect, for the purposes of exemplary illustration of the preferred embodiment of the present invention. According to the Seebeck Effect, a voltage is generated in a loop containing two dissimilar metals, provided two junctions of the two dissimilar metals are maintained at different temperatures.

The thermoelectric converter 36 is generally a hermetical housed device. The thermoelectric converter 36 includes a heat input port 360, a power output port 368, electroconductive plates 362, 365, 366, a first metal strip 363, and a second metal strip 364. The heat input port 360 is coupled to a second end of the heatpipe 35, the second end being opposite from the first end. The electroconductive plates 362, 365, 366 and the first and second metal strips 363, 364 cooperatively form a loop. The first and second metal strips 363, 364 are formed of different kinds of thermoelectric metals.

A thermo-conductive plate 361 is interposed between the heatpipe 35 and the electroconductive plate 362. The thermo-conductive plate 361 is thereby positioned and configured for supplying heat energy to the first and second metal strips 363, 364. The electroconductive plate 362 is secured to the thermo-conductive plate 361. First ends of the first and second metal strips 363, 364 (these first ends also being also referred to as “hot ends”) are electrically and thermally connected with the electroconductive plate 362. The electroconductive plates 365, 366 are electrically connected with opposite second ends of the first and second metal strips 363, 364 (these second ends also being referred to as “cool ends”). The electroconductive plates 365, 366 are, in turn, electrically connected with the power output port 368 via electrical wires (not labeled).

As stated above, the first and second metal strips 363, 364 are formed of different kinds of thermoelectric metals. At least one of the thermoelectric metals is preferably a bismuth-tellurium alloy. Applications and capabilities of bismuth-tellurium alloys are reported in an article by Harman et al., entitled “Quantum Dot Superlattice Thermoelectric Materials and Devices” (Science, Vol. 297, Feb. 27, 2002), and in an article by Duck-Young Chung, entitled “CsBi₄Te₆: A High-Performance Thermoelectric Material for Low-Temperature Applications” (Science, Vol. 287, Feb. 11, 2000). Further, such applications and capabilities are disclosed in China Patent No. 02121431.X. All three of these publications are incorporated herein by reference.

The first and second metal strips 363, 364 can alternatively be formed of conventional thermocouple materials, such as a nickel-chromium alloy or a nickel-copper alloy, according to the requirements of particular applications.

In the illustrated embodiment, the computer 3 can be a desktop computer or a notebook computer. The computer further comprises a display screen 40 that is electrically connected with the power output port 368. The display screen 40 is, advantageously, a thin film transistor liquid crystal display (TFT LCD). In other exemplary embodiments, the power output port 368 can be connected to other electronic elements mounted on the motherboard 31. Alternatively, the power output port 368 can be electrically connected and thereby configured for charging of a secondary battery.

The heatpipe 35 preferably contains a circulatory working fluid containing a plurality of heat-conductive nanoparticles therein, for providing improved thermal conductivity of the heatpipe 35. The thermal interface material 33 preferably comprises a polymer matrix and at least one of carbon nanotubes, cabon nanocapsules, and/or a metallic nano material (nanoparticles or some nanostructure) incorporated in the polymer matrix. The method for making such thermal interface material, advantageously includes the steps of: providing a nano-material, e.g. at least one of carbon nanotubes, cabon nanocapsules, and/or a metallic nano material, immersing the nano-material in a liquid prepolymer such that the liquid prepolymer infuses into the nano-material; and polymerizing the liquid prepolymer to obtain a matrix having the nano-material secured therein.

It should be noted that for the purposes of illustrating one embodiment of the present invention, the above-described thermoelectric converter 36 that operates based on the Seebeck Effect has been described. Thus, heat energy is converted into electric energy. Similarly, any of a variety of conventional thermoelectric converters known to those skilled in the art may be suitably adopted. For instance, the thermoelectric converter 36 may be a fuel battery thermoelectric converter that operates based on electrochemical reactions. In other words, the thermoelectric converter 36 that operates based on the Seebeck Effect is provided herein for illustration purposes only and is not intended to limit the present invention.

The thermal interface material 33, the thermo-conductive block 34, the heat conductive device 35, and the thermoelectric converter 36 can together be considered to comprise a heat recycling system 37. This heat recycling system 37 has potential application beyond use with computers. The heat recycling system 37 could advantageously be used to simultaneously dissipate heat and recover energy from any various heat-generating devices (e.g., electronic devices, optical devices, audio systems, and/or engines/motors), especially those which could benefit from the recovered electrical energy. The heat recycling system 37 could be particularly advantageous for energy recovery when used in combination with computers, electronic devices, optical devices, lighting units, audio systems, or other electrical or electromechanical systems, which, if wired appropriately, could directly use the recovered electric power to aid in running those particular systems and/or could store it for later use (e.g., as a back-up power source in case of a power failure).

It is to be further understood that the above-described embodiments illustrate the scope of the invention but do not restrict the scope of the invention. Variations may be made to the embodiments without departing from the spirit or scope of the invention as claimed herein.

What is claimed is:

1. A computer comprising:
a circuit board;
a heat-generating device mounted on the circuit board;
a heat-conducting device attached to the heat-generating device, the heat-conducting device being configured for absorbing heat energy generated by the heat-generating device; and
a thermoelectric converter coupled to the heat-dissipating device, the thermoelectric converter being configured for converting the heat energy into electrical energy.

2. The computer as described in claim 1, wherein the heat-conducting device comprises a heatpipe.

3. The computer as described in claim 2, further comprising a heat-conducting plate interposed between the heatpipe and the heat-generating device.

4. The computer as described in claim 2, wherein the heatpipe contains a circulatory working fluid, the working fluid containing nano-sized particles therein.

5. The computer as described in claim 4, wherein the nano-sized particles are selected from the group consisting of carbon nanotubes, carbon nanocapsules, and a metallic nano material.

6. The computer as described in claim 1, further comprising a thermally conductive interface material interposed between the heat-generating device and the heat-conducting device.

7. The computer as described in claim 1, further comprising a secondary battery electrically connected with the thermoelectric converter and charged by the thermoelectric converter.

8. The computer as described in claim 1, further comprising a display screen, the display screen being electrically connected with the thermoelectric converter and powered by the thermoelectric converter.

9. The computer as described in claim 8, wherein the display screen comprises a thin film transistor liquid crystal display.

10. The computer as described in claim 1, wherein the thermoelectric converter is electrically connected to the circuit board, the thermoelectric converter powering one or more components mounted on the circuit board.

11. The computer as described in claim 1, wherein the thermoelectric converter comprises a circuit with two strips connected in series, the two strips each being comprised of a different kind of thermoelectric metal, relative to one another, corresponding ends of the two strips being coupled to the heat-conducting device, each of the ends being configured for receiving heat energy from the heat-conducting device.

12. The computer as described in claim 11, wherein at least one of the thermoelectric metals comprises a bismuth-tellurium alloy.

13. A heat-recycling system for converting heat energy received from a heat-generating device into electrical energy, the heat-recycling system comprising:
a heat-conducting device operatively coupled with the heat-generating device, the heat-conducting device being configured for absorbing heat energy generated by the heat-generating device, the heat-conducting device comprising a heatpipe, the heatpipe containing a working fluid, the working fluid having nano-sized particles therein, the nano-sized particles being comprised of one of carbon and a metallic material; and
a thermoelectric converter coupled to the heat-dissipating device, the thermoelectric converter being configured for converting the heat energy into electrical energy.

14. The heat-recycling system as described in claim 13, wherein the thermoelectric converter comprises a circuit with two strips connected in series, the two strips each being comprised of a different kind of thermoelectric metal, relative to one another, corresponding ends of the two strips each having corresponding first strip ends, the first strip ends being coupled to the heat-conducting device, each of the first strip ends being configured for receiving heat energy from the heat-conducting device.

15. The heat-recycling system as described in claim 13, further comprising at least one of the following:
a heat-conducting plate operatively positioned between the heat-conducting device and the heat-generating device; and
a thermally conductive interface material interposed between the heat-generating device and the heat-conducting device.
